(19) United States
(12) Patent Application Publication
(10) Pub. No.: US 2026/0214845 A1
(43) Pub. Date: Jul. 23, 2026

(54) IMMERSION LIQUID COOLING SYSTEM

(71) Applicant: Beijing Youzhuju Network Technology Co., Ltd., Beijing (CN)

(72) Inventors: Ting TIAN, Beijing (CN); Qi ZHANG, Beijing (CN); Tangbo JING, Beijing (CN); Jian WANG, Beijing (CN)

(21) Appl. No.: 19/143,316

(22) PCT Filed: Jan. 11, 2024
(86) PCT No.: PCT/CN2024/071891

§ 371 Date: Jun. 25, 2025

(30) Foreign Application Priority Data
Jan. 20, 2023 (CN) 202310087732.8

(51) Int. Cl. H05K 7/20

(52) U.S. Cl. CPC H05K 7/20272; H05K 7/20236; H05K 7/20263

(57) ABSTRACT

An immersion liquid cooling system, including: an immersion tank for accommodating a cooling liquid and an electronic device at least partially immersed in the cooling liquid, an air cavity located above a liquid level of the cooling liquid being formed in the immersion tank; a heat exchange unit for cooling the cooling liquid; and a bubble generation device including an air pump, a suction pipe an exhaust pipe, and a bubble exhaust channel, wherein the air pump is connected to the suction pipe and the exhaust pipe to suck air via the suction pipe and exhaust air via the exhaust pipe, a suction port of the suction pipe is disposed in the air cavity, the exhaust pipe is connected to the bubble exhaust channel, the bubble exhaust channel is disposed below the electronic device, the bubble exhaust channel includes a plurality of air ejection holes for ejecting bubbles.

### CROSS REFERENCE TO RELATED APPLICATIONS

This application claims priority of the Chinese invention patent application No. 202310087732.8, filed on Jan. 20, 2023, and entitled “IMMERSION LIQUID COOLING SYSTEM,” the entirety of which is incorporated herein by reference.

### FIELD

Embodiments of the present disclosure generally relate to a technical field of electronic device cooling, and more particularly, to an immersion liquid cooling system.

### BACKGROUND

Energy consumption of a data center is increased day by day, and a traditional air cooling heat dissipation solution is low in heat dissipation efficiency and needs to consume a large amount of energy, so that a demand of a data center cannot be met increasingly in cooling capacity and economic feasibility. A liquid cooling heat dissipation solution becomes an important technical direction for construction of the data center due to high heat dissipation efficiency.

At present, a relatively mature liquid cooling heat dissipation solution includes cold plate liquid cooling and immersion liquid cooling, wherein the immersion liquid cooling is divided into single-phase immersion liquid cooling and two-phase immersion liquid cooling. The immersion liquid cooling immerses an electronic device in a cooling liquid, heat generated by the electronic device may be taken away by the cooling liquid, the heat dissipation efficiency of such a heat dissipation manner is high, and a low power usage efficiency (PUE) is easier to be obtained. In addition, fanless design of the immersion liquid cooling can also save a large amount of energy consumption.

For the two-phase immersion liquid cooling solution, the heat generated by the electronic device may be taken away by phase change latent heat of the cooling liquid, so that heat dissipation requirement of a high-power-density device can be supported. However, since the cooling liquid required by the two-phase immersion liquid cooling solution needs to have high volatility and an air pressure of a two-phase immersion liquid cooling system is high, the loss of the cooling liquid becomes a main cost source for the two-phase immersion liquid cooling. In order to avoid volatilization of the cooling liquid, design of the two-phase immersion liquid cooling system is complicated, and technical threshold is high.

Since the single-phase immersion liquid cooling solution only dissipates heat by means of the heat exchange between the cooling liquid and a heating component, design of a single-phase immersion liquid cooling system is typically simpler, and it is widely used in industry.

However, the conventional immersion liquid cooling solution is easy to form a local hot spot, and heat exchange efficiency needs to be further improved.

### SUMMARY

It is an object of the present disclosure to provide an immersion liquid cooling system to at least partially solve the above problems and other potential problems.

In an aspect of the present disclosure, there is provided an immersion liquid cooling system, including: an immersion tank for accommodating a cooling liquid and an electronic device to be cooled, wherein the electronic device to be cooled is at least partially immersed in the cooling liquid, and an air cavity located above a liquid level of the cooling liquid is formed in the immersion tank; a heat exchange unit for cooling the cooling liquid with an external cold source; and a bubble generation device, including an air pump, a suction pipe, an exhaust pipe and a bubble exhaust channel, wherein the air pump is connected to the suction pipe and the exhaust pipe to suck air via the suction pipe and exhaust air via the exhaust pipe, a suction port of the suction pipe is disposed in the air cavity, the exhaust pipe is connected to the bubble exhaust channel, the bubble exhaust channel is disposed below the electronic device to be cooled, and the bubble exhaust channel includes a plurality of air ejection holes for ejecting bubbles towards the electronic device to be cooled.

In some embodiments, the heat exchange unit is disposed between the electronic device to be cooled and the bubble exhaust channel, the plurality of air ejection holes are disposed towards the heat exchange unit, and the heat exchange unit is connected to the external cold source through an external cold liquid supply pipe and an external cold liquid return pipe.

In some embodiments, the plurality of air ejection holes include a plurality of groups of air ejection holes spaced apart from each other.

In some embodiments, the air pump is disposed in the immersion tank.

In some embodiments, the air pump is submerged in the cooling liquid.

In some embodiments, the air pump is disposed adjacent to a side wall of the immersion tank, and the suction pipe and the exhaust pipe are disposed vertically adjacent to a side wall of the immersion tank.

In some embodiments, the air pump is disposed outside the immersion tank.

In some embodiments, at least one of the suction pipe and the exhaust pipe is provided with a component for absorbing or condensing steam of the cooling liquid.

In some embodiments, the immersion liquid cooling system is a single-phase immersion liquid cooling system or a two-phase immersion liquid cooling system.

In some embodiments, the immersion liquid cooling system further includes one or more air guide pipes disposed in the immersion tank, an air inlet end of the one or more air guide pipelines is disposed in correspondence with a corresponding air ejection hole on the bubble exhaust channel, and an air outlet end of the one or more air guide pipelines is disposed below a respective high power component in the electronic device to be cooled.

In some embodiments, at least one air guide pipeline of the one or more air guide pipelines includes an air inlet end and at least two air outlet ends.

In some embodiments, the air inlet end of the one or more air guide pipelines at least partially surrounds the respective air ejection hole on the bubble exhaust channel.

In embodiments according to the present disclosure, the air pump can extract air from the air cavity at the top of the immersion tank via the suction pipe, and then exhaust the air from the air ejection hole on the bubble exhaust channel via the exhaust pipe, and since density of the air is lower than that of the cooling liquid, the jetted air will form the bubbles under an action of the natural buoyancy force, a quasi-boiling effect is formed in the cooling liquid, and the bubbles return to the air cavity after passing through the cooling liquid, thereby forming an internal air circulation path in a reciprocating manner. In this way, overall temperature uniformity of the cooling liquid can be enhanced with the quasi-boiling effect formed by consuming lower energy, meanwhile, turbulence degree is enhanced due to disturbance caused by a large number of bubbles around the heating component, so that a local heat exchange coefficient is increased, and a local heat dissipation bottleneck of the high-power component is broken through.

It should be understood that the content described in this content section is not intended to limit key features or important features of the embodiments of the present disclosure, nor is it intended to limit a scope of the present disclosure. Other features of the present disclosure will become readily understood from following description.

### BRIEF DESCRIPTION OF DRAWINGS

The above and other features, advantages, and aspects of various embodiments of the present disclosure will become more apparent from following detailed description taken in conjunction with drawings. In the drawings, the same or similar reference numbers refer to the same or similar elements, wherein:

FIGS. 1 and 2 illustrate schematic structural diagrams of conventional immersion liquid cooling systems;

FIG. 3 illustrates a schematic structural diagram of an immersion liquid cooling system according to an embodiment of the present disclosure;

FIG. 4 illustrates a schematic structural diagram of an immersion liquid cooling system according to another embodiment of the present disclosure; and FIG. 5 illustrates a schematic structural diagram of an air guide pipeline according to an embodiment of the present disclosure.

### DETAILED DESCRIPTION

Preferred embodiments of the present disclosure will be described in more detail below with reference to the drawings. While the preferred embodiments of the present disclosure are shown in the drawings, it should be understood that the present disclosure may be implemented in various forms and should not be limited by embodiments set forth herein. Rather, these embodiments are provided to make this disclosure more thorough and complete, and to fully convey a scope of the present disclosure to those skilled in the art.

As used herein, the term “including” and variations thereof represent openness, i.e., “including but not limited to”. Unless specifically stated, the term “or” means “and/or”. The term “based on” means “based at least in part on”. The terms “an example embodiment” and “an embodiment” mean “at least one example embodiment”. The term “another embodiment” means “at least one further embodiment”. The terms “first,” “second,” and the like may refer to different or identical objects.

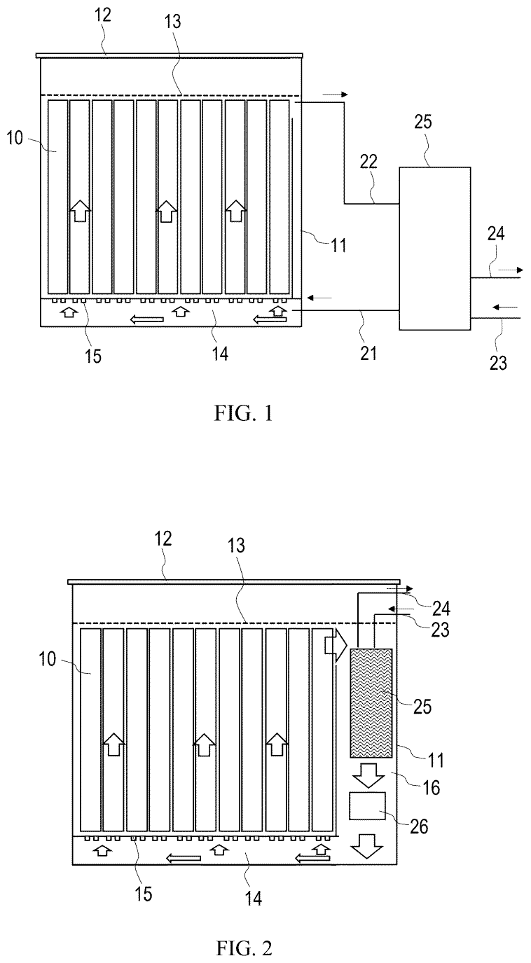

As described above, the conventional immersion liquid cooling solution is easy to form a local hot spot, and the heat exchange efficiency needs to be further improved. Exemplary structural and operating principles of conventional immersion liquid cooling systems will be described below in conjunction with FIGS. 1 and 2.

FIG. 1 illustrates a schematic structural diagram of a single-phase immersion liquid cooling system. As shown in FIG. 1, an immersion tank 11 is filled with a cooling liquid, and the electronic device 10 is located in the immersion tank 11 and immersed by the cooling liquid. A liquid level 13 of the cooling liquid is higher than a top of the electronic device 10, that is, the electronic device 10 is completely immersed by the cooling liquid. The immersion tank 11 may be provided with a tank upper cover 12, and the electronic device 10 may be conveniently operated, for example, a plug and unplug operation, by opening the tank upper cover 12. An external heat exchange unit 25 and the immersion tank 11 are connected through a cooling liquid supply pipe 21 and a cooling liquid return pipe 22. A pump (not shown) disposed in the heat exchange unit 25 may inject cooled cooling liquid into a bottom flow channel 14 of the immersion tank 11 via the cooling liquid supply pipe 21. The cooling liquid flows in a direction towards the electronic device 10 via a liquid ejection hole 15 disposed on the bottom flow channel 14. After the cooling liquid flows uniformly through the electronic device 10 from bottom to top, heated cooling liquid returns to the heat exchange unit 25 via the cooling liquid return pipe 22. The heat exchange unit 25 may be connected to an external cold source (not shown) through an external cold liquid supply pipe 23 and an external cold liquid return pipe 24. In this way, the heat exchange unit 25 may use cold quantity provided by the external cold source to cool the cooling liquid returned via the cooling liquid return pipe 22, so as to exchange heat dissipated by the electronic device 10 to an external cooling circulation, and finally to the external cold source.

FIG. 2 illustrates a schematic structural diagram of another single-phase immersion liquid cooling system. Different from the immersion liquid cooling system shown in FIG. 1, the heat exchange unit 25 in the single-phase immersion liquid cooling system shown in FIG. 2 is disposed in the immersion tank 11. The immersion tank 11 is provided with a side flow channel 16 and a bottom flow channel 14. The heat exchange unit 25 is disposed in the side flow channel 16 for cooling the cooling liquid in the side flow channel 16. A circulating pump 26 is disposed below the heat exchange unit 25 and configured to drive the cooling liquid in the side flow channel 16 to flow into the bottom flow channel 14. The cooling liquid flows in a direction towards the electronic device 10 via the liquid ejection hole 15 disposed on the bottom flow channel 14. After the cooling liquid flows uniformly through the electronic device 10 from bottom to top, heated cooling liquid returns to the side channel 16 again, and then is cooled by the heat exchange unit 25. The heat exchange unit 25 may be connected to the external cold source through the external cold liquid supply pipe 23 and the external cold liquid return pipe 24. In this way, the heat exchange unit 25 can cool the cooling liquid returned to the side flow channel 16 with cold quantity provided by the external cold source, so as to exchange heat dissipated by the electronic device 10 to the external cooling circulation, and finally to the external cold source.

The single-phase immersion liquid cooling system is simple in structure and high in reliability, and is a widely used immersion liquid cooling system in industry. However, the conventional single-phase immersion liquid cooling systems as shown in FIGS. 1 and 2 has following disadvantages.

In the conventional single-phase immersion liquid cooling systems, overall flow rate of the cooling liquid is low, and a non-uniformity of the flow can easily cause local hot spots. Even in a case where the cooling liquid flows uniformly, flow rates of the cooling liquid obtained adjacent to the heating component and non-heating component are almost the same. Most of the cooling liquid flowing on a surface of the heating component is laminar, and the heat exchange coefficient thereof is not high. In addition, it is difficult to design or add a moving component (for example, a fan, a pump, etc.) in the immersion tank 11 to increase the flow rate of the cooling liquid, so it is easy to encounter a heat dissipation bottleneck when a power density of the heating component is large.

In addition, in the conventional single-phase immersion liquid cooling systems, if only the flow rate of the cooling liquid in the immersion tank 11 is increased wholly by increasing a driving force of the pump to enhance the heat dissipation capacity of the single heating component, the effect of this method is not significant for increasing local heat dissipation capacity of the device. In addition, and cost of this method is large. Specifically, the power of the pump increases exponentially as its lift increases, and this solution will become infeasible after a certain flow rate is exceeded. In addition, when overall flow rate of the cooling liquid is increased, for the single-phase immersion liquid cooling system disposed in the heat exchange unit 25 shown in FIG. 2, the side flow channel 16 and the bottom flow channel 14 reserved in the immersion tank 11 also need to be increased accordingly, and for the single-phase immersion liquid cooling system external to the heat exchange unit 25 shown in FIG. 1, pipeline design needs to be increased, which greatly reduces space utilization rate of the immersion tank 11, increases an invalid utilization volume of the cooling liquid, and improves overall cost of the single-phase immersion liquid cooling system.

In addition, in the conventional single-phase immersion liquid cooling systems, for the requirement of enhancing local heat exchange performance, it is currently widely used in the industry to design a heat dissipation apparatus on the heating component, for example, adapting a copper heat dissipation plate, or adapting a two-dimensional (2D) vapor chamber or even a three-dimensional (3D) vapor chamber with a higher price to enhance the local heat exchange capability of the heating component. However, as the power density of the heating component is further improved, the single-phase immersion liquid cooling solution also encounters a heat dissipation bottleneck.

In addition, in the conventional single-phase immersion liquid cooling systems, the cooling liquid flows integrally in the immersion tank 11 under driving of the pump, and dependency on the heat exchange unit 25 is large in the architecture. Regardless of an internal heat exchange unit 25 or an external heat exchange unit 25, the pump in the heat exchange unit 25 needs to have high redundancy, it is difficult to achieve consistency with other forms of liquid cooling form (such as cold plate liquid cooling) in terms of a data center architecture.

In the two-phase immersion liquid cooling system, heating of the high-power-density component may cause the cooling liquid nearby to partially boil, so that the heat generated by the component is taken away by a latent heat of the phase change of the cooling liquid. Evaporated cooling liquid may be cooled by a heat exchange coil disposed at the top of the immersion tank or a condensing apparatus disposed outside the immersion tank, thereby condensing again to a liquid state. In the two-phase immersion liquid cooling systems, in addition to partial boil of the cooling liquid, the cooling liquid does not flow in other ways, and this phase change liquid cooling mode also encounters a heat dissipation bottleneck. For example, since an area of the heating component is limited and a surface is relatively smooth, a large bubble may be generated when the cooling liquid is boiled, resulting in a large local thermal resistance and a low heat exchange efficiency. In order to improve a boiling heat exchange capacity of the surface of the component, the industry often adapts a method of sintering a powder on a heat dissipation surface or using a special material to enhance a boiling effect, so that the boiling is more severe, and the large bubbles are changed into small bubbles, so as to avoid the heat resistance and boiling effect loss caused by too large bubbles and the bubbles not falling off for a long time. However, since the boiling in the two-phase immersion liquid cooling systems mainly occurs locally, a flow effect of the cooling liquid is poor, it is difficult to cause the cooling liquid to flow by adding the pump, so that temperature distribution of the cooling liquid is uneven, and the heat exchange efficiency is low.

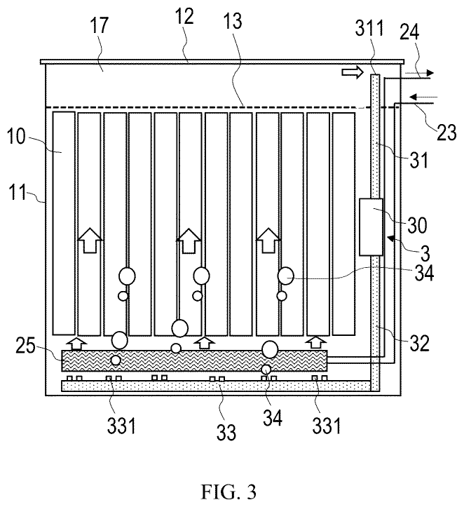

Embodiments of the present disclosure provide an immersion liquid cooling system to at least partially solve the above problems. The principles of the present disclosure will be described below in conjunction with FIGS. 3-5.

FIG. 3 illustrates a schematic structural diagram of an immersion liquid cooling system according to an embodiment of the present disclosure. As shown in FIG. 3, the immersion liquid cooling system described herein is a single-phase immersion liquid cooling system, which generally includes an immersion tank 11, a heat exchange unit 25, and a bubble generation device 3.

As shown in FIG. 3, the immersion tank 11 is filled with a cooling liquid, and an electronic device 10 to be cooled is located in the immersion tank 11 and immersed by the cooling liquid. A liquid level 13 of the cooling liquid is higher than a top of the electronic device 10, that is, the electronic device 10 is completely immersed by the cooling liquid. In some embodiments, the electronic device 10 may also be only partially submerged in the cooling liquid, and a portion of non-heating components may not be immersed in the cooling liquid. The immersion tank 11 may be provided with a tank upper cover 12, and the electronic device 10 may be conveniently operated, for example, a plug and unplug operation, by opening the tank upper cover 12. An air cavity 17 located above the liquid level 13 of the cooling liquid is formed in the immersion tank 11.

In some embodiments, the cooling liquid may include a fluorinated liquid or a mineral oil. In other embodiments, the cooling liquid may also be other types, and the embodiments of the present disclosure are not strictly limited in this aspect.

In some embodiments, the electronic device 10 may include an Internet device (also referred to as an IT device), such as a server or a switch. In other embodiments, the electronic device 10 may be other types, and the embodiments of the present disclosure are not strictly limited in this aspect.

The heat exchange unit 25 is disposed in the immersion tank 11 for cooling the cooling liquid in the immersion tank 11 with an external cold source. The heat exchange unit 25 may be connected to the external cold source through an external cold liquid supply pipe 23 and an external cold liquid return pipe 24 to receive additional cooling liquid from the external cold source via the external cold liquid supply pipe 23, and return heated additional cooling liquid to the external cold source via the external cold liquid return pipe 24. The additional cooling liquid may include cooling water or other types of cooling liquid, which is not limited in the embodiments of the present disclosure. With the above arrangement, the heat exchange unit 25 may cool the cooling liquid in the immersion tank 11 with the cold quantity provided by the external cold source, so as to exchange the heat dissipated by the electronic device 10 to the external cooling circulation, and finally to the external cold source.

In some embodiments, the heat exchange unit 25 may include a plate heat exchanger. In other embodiments, the heat exchange unit 25 may include other types of heat exchangers, and the embodiments of the present disclosure are not strictly limited in this aspect.

In some embodiments, as shown in FIG. 3, the bubble generation device 3 includes an air pump 30, a suction pipe 31, an exhaust pipe 32, and a bubble exhaust channel 33. The air pump 30 is disposed in the immersion tank 11 and is connected to the suction pipe 31 and the exhaust pipe 32 to suck air via the suction pipe 31 and exhaust air via the exhaust pipe 32. A suction port 311 of the suction pipe 31 is disposed in the air cavity 17 to suck air from the air cavity 17. The exhaust pipe 32 is connected to the bubble exhaust channel 33 to convey the air to the bubble exhaust channel 33. The bubble exhaust channel 33 is disposed below the electronic device 10. The bubble exhaust channel 33 includes a plurality of air ejection holes 331 for ejecting bubbles 34 towards the electronic device 10 to be cooled.

With the above arrangement, the air pump 30 can extract air from the air cavity 17 at the top of the immersion tank 11 via the suction pipe 31, and then exhaust the air from the air ejection hole 331 on the bubble exhaust channel 33 via the exhaust pipe 32, and since density of the air is lower than that of the cooling liquid, the jetted air will form the bubbles 34 under an action of natural buoyancy force. The bubbles 34 are continuously ejected from the air ejection holes 331 to form a quasi-boiling effect in the cooling liquid. The bubbles 34 pass through the cooling liquid and return to the air cavity 17, thereby forming an internal air circulation path in a reciprocating manner. After the cooling liquid is heated by the electronic device 10, the hot cooling liquid rises to form convection under the action of the natural buoyancy force, and under the action of the quasi-boiling effect formed by a large number of bubbles 34, such convection is further enhanced. In this way, overall temperature uniformity of the cooling liquid can be enhanced with the quasi-boiling effect formed by consuming lower energy, meanwhile, due to disturbance caused by the large number of bubbles 34 around the heating component in the electronic device 10, turbulence degree is enhanced, such that a local heat exchange coefficient is increased, the heat exchange efficiency is enhanced, and a local heat dissipation bottleneck of the high-power component is broken through. In addition, by adopting the quasi-boiling effect, the plate type heat exchanger can be solely disposed in the immersion tank 11, the immersion tank 11 may be connected to the external cold source only by means of the external cold liquid supply pipe 23 and the external cold liquid return pipe 24, such that simplicity of a data center architecture can be achieved, and the structure is easier to be consistent with a cold plate data center architecture. In addition, due to adoption of the internal air circulation path, an evaporation loss of the cooling liquid can be reduced.

In some embodiments, as shown in FIG. 3, the heat exchange unit 25 is disposed between the electronic device 10 to be cooled and the bubble exhaust channel 33. The plurality of air ejection holes 331 are disposed towards the heat exchange unit 25. With such an arrangement, the bubbles 34 ejected from the air ejection holes 331 first pass through the heat exchange unit 25, enhance upward convection of the cooling liquid adjacent to the heat exchange unit 25, and further improve the heat exchange efficiency. In other embodiments, the heat exchange unit 25 may also be disposed at other positions in the immersion tank 11, for example, as shown in FIG. 2, close to a side wall of the immersion tank 11. In other embodiments, the heat exchange unit 25 may also be disposed outside the immersion tank 11, for example, as shown in FIG. 1.

In some embodiments, as shown in FIG. 3, the plurality of air ejection holes 331 include a plurality of groups of air ejection holes 331 spaced apart from each other. Each group of air ejection holes 331 is disposed below a corresponding heating component in the electronic device 10. With this arrangement, the turbulence degree at each heating component can be enhanced, and the heat exchange efficiency can be improved. In other embodiments, the plurality of air ejection holes 331 may adopt other arrangements, which are not limited in the embodiments of the present disclosure.

In some embodiments, as shown in FIG. 3, the air pump 30 is immersed in the cooling liquid. In some embodiments, the air pump 30 may also be disposed in the air cavity 17. In some embodiments, as shown in FIG. 3, the air pump 30 may be disposed adjacent to a side wall of the immersion tank 11, and the suction pipe 31 and the exhaust pipe 32 are disposed vertically adjacent to a side wall of the immersion tank 11.

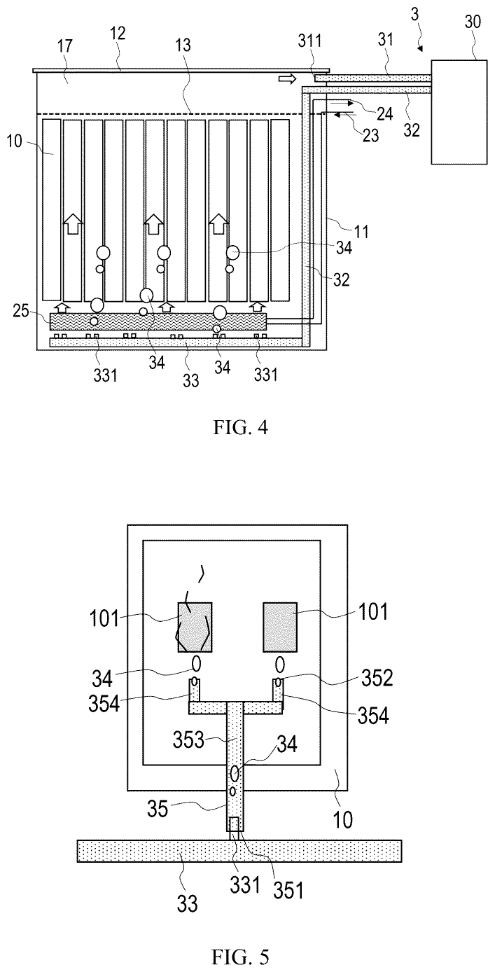

FIG. 4 illustrates a schematic structural diagram of an immersion liquid cooling system according to another embodiment of the present disclosure. A structure of the immersion liquid cooling system shown in FIG. 4 is similar to that of the immersion liquid cooling system shown in FIG. 3, except that the air pump 30 in the immersion liquid cooling system shown in FIG. 4 is disposed outside the immersion tank 11. Only difference therebetween will be described in detail below, and will not be repeated for the same part.

As shown in FIG. 4, an air pump 30 is disposed outside the immersion tank 11. The air pump 30 is connected to a suction pipe 31 and an exhaust pipe 32 to suck air via the suction pipe 31 and exhaust air via the exhaust pipe 32. A suction port 311 of the suction pipe 31 is disposed in an air cavity 17 to suck air from the air cavity 17. The exhaust pipe 32 is connected to a bubble exhaust channel 33 to convey the air to the bubble exhaust channel 33. The bubble exhaust channel 33 is disposed below the electronic device 10 to eject bubbles 34 towards the electronic device 10 to be cooled via a plurality of air ejection holes 331. By arranging the air pump 30 outside the immersion tank 11, structural design in the immersion tank 11 is simplified, and system reliability can be enhanced. In addition, the external air pump 30 can simultaneously provide a quasi-boiling effect to the plurality of immersion tanks 11, which is more concise in structural design.

In some embodiments, at least one of the suction pipe 31 and the exhaust pipe 32 may be provided with a component for absorbing or condensing steam of the cooling liquid. For example, external cold may be coupled to at least one of the suction pipe 31 and the exhaust pipe 32 to transform vapor of the cooling liquid back into liquid. By utilizing such a component, an evaporation loss of the cooling liquid can be reduced.

As described above, in the conventional single-phase immersion liquid cooling solution, it is difficult to design or add a moving component (such as a fan, a pump, etc.) through the flow channel in the electronic device 10 to increase the flow rate of the cooling liquid; it is also difficult to improve the overall flow rate of the liquid in the immersion tank by increasing a lift of the pump in the heat exchange unit to enhance the heat dissipation capability of the heating component. According to the embodiment of the present disclosure, by utilizing the quasi-boiling effect, only a simple local flow channel design with low cost can be used for breaking confusion of difficult local heat exchange enhancement of the conventional single-phase immersion liquid cooling.

In some embodiments, in order to further improve the heat dissipation performance of the high-power component 101 in the electronic device 10, the immersion tank 11 is provided with one or more air guide pipelines 35 for guiding the bubbles 34 to the corresponding high-power component 101, as shown in FIG. 5. An air inlet end 351 of the air guide pipeline 35 is disposed in correspondence with the corresponding air ejection hole 331 on the bubble exhaust channel 33, and the air outlet end 352 of the air guide pipeline 35 is disposed below the corresponding high-power component 101 in the electronic device 10 to be cooled. Due to a buoyancy effect of the bubbles 34 in the cooling liquid, the air guide pipeline 35 can adopt a very simple flexible pipeline design, and when the air guide pipeline 35 is interfaced with the air ejection hole 331, an air tightness problem does not need to be excessively considered, and a special joint does not need to be designed. It is only necessary to place the air inlet end 351 of the air guide pipelines 35 at the air ejection hole 331, and a horizontal size is slightly larger than the air ejection hole 331 to achieve purpose of air guide.

In some embodiments, as shown in FIG. 5, the air inlet end 351 of the one or more air guide pipelines 35 at least partially surrounds the respective air ejection hole 331 on the bubble exhaust channel 33. In other words, a height of the air inlet end 351 may be lower than a height of a top end of the air ejection hole 331. In other embodiments, the height of the air inlet end 351 may be substantially flush with the height of the top end of the air ejection hole 331, or slightly higher than the height of the top end of the air ejection hole 331, which may also guide the bubbles 34 to the respective high-power component 101.

By inducing a localized jet effect adjacent to the high-power component 101 with the air guide pipeline 35 under a boiling effect, the heat dissipation capability of the high-power component 101 can be enhanced at a lower cost.

In some embodiments, a large air ejection hole 331 may be provided for the high-power component 101 that needs to enhance heat exchange, and air is guided through the air guide pipeline 35 to guide more bubbles to the high-power component 101 that needs to enhance heat exchange.

In an embodiment, as shown in FIG. 5, at least one of the one or more air guiding pipelines 35 includes an air inlet end 351 and two air outlet ends 352. The air guide pipeline 35 comprises a main pipeline 353 and two branch pipelines 354, the air inlet end 351 is disposed on the main pipeline 353, and the two air outlet ends 352 are respectively disposed on the two branch pipelines 354. With this arrangement, the same air guide pipeline 35 can be used to simultaneously guide air to the two high-power components 101. In other embodiments, the at least one air guide pipeline 35 may include more air outlet ends 352.

The principles of the present disclosure are described above in connection with the single-phase immersion liquid cooling system shown in FIGS. 3 and 4. It should be understood, however, that the bubble generation device 3 described herein may also be applied in a two-phase immersion liquid cooling system. The two-phase immersion liquid cooling system may also have an immersion tank 11 and a heat exchange unit 25. The immersion tank 11 may have a structure and arrangement as described above. The heat exchange unit 25 may be disposed in the immersion tank 11 or outside the immersion tank 11 for cooling the cooling liquid in the immersion tank 11. In the two-phase immersion liquid cooling system, the heating of the high-power-density component causes the cooling liquid nearby to partially boil, so that the heat generated by the component is taken away by the latent heat of the phase change of the cooling liquid. The evaporated cooling liquid may be cooled by a heat exchange coil disposed in the air cavity 17 or a condensing device disposed outside the immersion tank 11, again condensing to a liquid state. In the two-phase immersion liquid cooling system, the quasi-boiling effect can also be adopted to enhance the overall temperature uniformity of the cooling liquid in the immersion tank 11, and the air guide pipeline 35 is used to guide the bubbles 34 to generate a local jet, which can also enhance the heat dissipation capability of the single component. In addition, bubbles generated by boiling of a heat dissipation surface of the accelerator can be prevented from falling off in time by strengthening local flow disturbance, so that an effect of enhancing boiling is achieved, and the heat dissipation efficiency is further improved.

Various embodiments of the present disclosure have been described above, which are exemplary, not exhaustive, and are not limited to the embodiments disclosed. Many modifications and variations will be apparent to those of ordinary skill in the art without departing from the scope and spirit of the illustrated embodiments. The selection of the terms used herein is intended to best explain the principles of the embodiments, practical applications, or technical improvements in a marketplace, or to enable others of ordinary skill in the art to understand the embodiments disclosed herein.

1. An immersion liquid cooling system, comprising:
an immersion tank for accommodating a cooling liquid and an electronic device to be cooled, wherein the electronic device to be cooled is at least partially immersed in the cooling liquid, and an air cavity located above a liquid level of the cooling liquid is formed in the immersion tank;
a heat exchange unit for cooling the cooling liquid with an external cold source; and
a bubble generation device comprising an air pump, a suction pipe, an exhaust pipe and a bubble exhaust channel, wherein the air pump is connected to the suction pipe and the exhaust pipe to suck air via the suction pipe and exhaust air via the exhaust pipe, a suction port of the suction pipe is disposed in the air cavity, the exhaust pipe is connected to the bubble exhaust channel, the bubble exhaust channel is disposed below the electronic device to be cooled, and the bubble exhaust channel comprises a plurality of air ejection holes for ejecting bubbles towards the electronic device to be cooled.

2. The immersion liquid cooling system of claim 1, wherein the heat exchange unit is disposed between the electronic device to be cooled and the bubble exhaust channel, the plurality of air ejection holes are disposed towards the heat exchange unit, and the heat exchange unit is connected to the external cold source through an external cold liquid supply pipe and an external cold liquid return pipe.

3. The immersion liquid cooling system of claim 1, wherein the plurality of air ejection holes comprise a plurality of groups of air ejection holes spaced apart from each other.

4. The immersion liquid cooling system of claim 1, wherein the air pump is disposed in the immersion tank.

5. The immersion liquid cooling system of claim 4, wherein the air pump is submerged in the cooling liquid.

6. The immersion liquid cooling system of claim 4, wherein the air pump is disposed adjacent to a side wall of the immersion tank, and the suction pipe and the exhaust pipe are disposed vertically adjacent to a side wall of the immersion tank.

7. The immersion liquid cooling system of claim 1, wherein the air pump is disposed outside the immersion tank.

8. The immersion liquid cooling system of claim 7, wherein at least one of the suction pipe and the exhaust pipe is provided with a component for absorbing or condensing steam of the cooling liquid.

9. The immersion liquid cooling system of claim 1, wherein the immersion liquid cooling system is a single-phase immersion liquid cooling system or a two-phase immersion liquid cooling system.

10. The immersion liquid cooling system of claim 1, further comprising one or more air guide pipelines disposed in the immersion tank, wherein an air inlet end of the one or more air guide pipelines is disposed in correspondence with the respective air ejection hole on the bubble exhaust channel, and an air outlet end of the one or more air guide pipelines is disposed below a respective high-power component in the electronic device to be cooled.

11. The immersion liquid cooling system of claim 10, wherein at least one air guide pipeline of the one or more air guide pipelines comprises an air inlet end and at least two air outlet ends.

12. The immersion liquid cooling system of claim 10, wherein the air inlet end of the one or more air guide pipelines at least partially surrounds the respective air ejection hole on the bubble exhaust channel.
